(19) United States
(12) Patent Application Publication
(10) Pub. No.: US 2021/0233740 A1
(43) Pub. Date: Jul. 29, 2021

(54) Charged Particle Microscope and Method of Imaging Sample

(71) Applicant: HITACHI HIGH-TECHNOLOGIES CORPORATION, Tokyo (JP)

(72) Inventors: Minami SHOUJI, Tokyo (JP); Natsuki TSUNO, Tokyo (JP); Yuusuke OOMINAMI, Tokyo (JP)

(73) Assignee: Hitachi High-Technologies Corporation, Tokyo (JP)

(21) Appl. No.: 16/094,281

(22) PCT Filed: Apr. 22, 2016
(86) PCT No.: PCT/JP2016/062697

§ 371 Date: Oct. 17, 2018

(51) Int. Cl. H01J 37/244; H01J 37/12

(52) U.S. Cl. CPC H01J 37/244; H01J 2237/24564; H01J 37/12

(57) ABSTRACT

The present invention provides an electron microscope and an observation method capable of observing secondary electrons in the atmosphere. In detail, a charged particle microscope of the invention includes: a partition wall that separates a non-vacuum space in which a sample is loaded from a vacuum space inside a charged particle optical lens barrel; an upper electrode; a lower electrode on which the sample is loaded; a power supply for applying a voltage to at least one of the upper electrode and the lower electrode; a sample gap adjusting mechanism for adjusting a gap between the sample and the partition wall; and an image forming unit for forming an image of the sample based on the current absorbed by the lower electrode. The secondary electrons are selectively measured by using an amplification effect due to ionization collision between electrons and gas molecules generated when a voltage is applied between the upper electrode and the lower electrode. As a detection method, a method is used which measures a current value flowing in a substrate.

### TECHNICAL FIELD

The present invention relates to a charged particle microscope for acquiring an image of a sample using a charged particle beam.

### BACKGROUND ART

From among microscopes, electron microscopes using electrons as light sources enable observation of surface morphology in nm order. From among the electron microscopes, a scanning electron microscope (hereinafter referred to as SEM) is widely used for observation of a fine surface morphology or observation of a composition structure. The SEM is an apparatus for scanning an electron beam (primary electron beam) focused on a sample surface by an electron lens through a deflector to detect and image emitted electrons generated in a region of the sample to which the electron beam is irradiated. The emitted electrons have energy equivalent to that of emitted electrons (hereinafter referred to as secondary electrons) with low energy having surface morphology information and a primary electron beam and include rear scattering electrons (hereinafter referred to as reflected electrons) having composition information.

In case of observing soft materials and biological samples, it is preferable to perform high-resolution observation under the atmospheric pressure at which no shape deformation and moisture evaporation occurs. However, since an electron beam is scattered by collision with gas molecules, the resolution thereof is degraded at the atmospheric pressure. Therefore, a lens barrel constituting an electro-optical system, such as an electron lens or a deflector, is vacuum-exhausted. Generally, in a SEM, since the lens barrel and an enclosure installed with a sample therein are vacuum-exhausted, the sample is placed under vacuum. For this reason, the electron microscope was not suitable for observing samples including moisture or samples that change their shapes depending on a pressure change.

Recently, a SEM has been widely used in which a sample can be held and observed under a desired pressure by providing a diaphragm or a fine hole through which an electron beam is transmittable between a lens barrel constituting an electro-optical system and an enclosure installed with a sample therein that need to be maintained vacuum. Therefore, a sample can be observed under the atmosphere or a desired gas pressure or with a desired type of gas. A method of irradiating an electron beam without contacting a diaphragm separating a lens barrel from an enclosure to a sample is called a diaphragm contactless-type method. A diaphragm contactless-type device has a non-vacuum space between a sample and a diaphragm, and a primary electron beam passes through the non-vacuum space and the sample is irradiated with the primary electron beam. Also, from among emitted electrons from the sample, reflected electrons with high energy which are less influenced by scattering due to gases, pass through the non-vacuum space between the sample and the diaphragm and the diaphragm and are detected by a detector installed in the lens barrel.

PTL 1 discloses a diaphragm contactless-type scanning electron microscope. The scanning electron microscope disclosed in PTL 1 includes a disk-shaped cathode electrode between a diaphragm separating a lens barrel from an enclosure and a sample, and a mechanism of forming an electric field between the corresponding electrode and the sample to amplify emitted electrons, thereby detecting the emitted electrons via the electrode.

### CITATION LIST

### Patent Literature

PTL 1: JP-A-2008-262886

### SUMMARY OF THE INVENTION

### Technical Problems

An advantage of a scanning electron microscope is that a surface image of a sample can be obtained by detecting secondary electrons. However, since the energy of secondary electrons is low, in an electron microscope capable of observing samples under the atmosphere or a desired gas pressure or with a desired type of gas, it is difficult to detect the secondary electrons, because the secondary electrons are scattered by gas molecules in a sample chamber and cannot be transmitted through a diaphragm.

In addition, since a detection electrode is provided directly above a sample in PTL 1, not only secondary electron signals amplified by an electric field, but also reflected electrons are detected. Therefore, it was difficult to distinguish secondary electrons from reflected electrons and to obtain an image including surface morphology information with the main contrast.

An object of the present invention is to obtain an image including surface morphology information with the main contrast in an electron microscope capable of observing a sample under the atmosphere or a desired gas pressure or with a desired type of gas.

### Solution to Problem

In order to solve the problem described above, according to the present invention, there is provided a charged particle microscope of the invention including: a partition wall that separates a non-vacuum space in which a sample is loaded from a vacuum space inside a charged particle optical lens barrel; an upper electrode; a lower electrode on which the sample is loaded; a power supply for applying a voltage to at least one of the upper electrode and the lower electrode; a sample gap adjusting mechanism for adjusting a gap between the sample and the partition wall; and an image forming unit for forming an image of the sample based on the current absorbed by the lower electrode. The secondary electrons are selectively measured by using an amplification effect due to ionization collision between electrons and gas molecules generated when a voltage is applied between the upper electrode and the lower electrode. As a detection method, a method is used which measures a current value flowing in a substrate.

### Advantageous Effects of the Invention

According to the invention, by measuring a current absorbed by an upper electrode or a lower electrode in synchronization with scanning of primary electrons, an image including surface morphology information with the main contrast can be obtained in an electron microscope capable of observing a sample under the atmosphere or a desired gas pressure or with a desired type of gas.

The problems, configurations, and effects other than those described above will be clarified from the following description of embodiments below.

### BRIEF DESCRIPTION OF DRAWINGS

FIG. 1 is a diagram illustrating a configuration of a device used in Embodiment 1.

FIG. 2 is a diagram illustrating a method of selectively acquiring secondary electrons under the atmospheric pressure.

FIG. 3 illustrates a result of a simulation indicating a relationship between electron energy and a mean free path in a space under the atmospheric pressure.

FIG. 4 is a diagram illustrating an example of a flowchart of selectively acquiring secondary electrons.

FIG. 5(a) is a diagram for describing an atmospheric pressure SEM image obtained from a reflected electron detector.

FIG. 5(b) is a diagram illustrating substrate current images indicating a relationship between an electric field and a sample GAP when the imaging method of Embodiment 1 is used.

FIG. 6 is a diagram illustrating the outline of a second enclosure kept under the atmosphere in Embodiment 2.

FIG. 7(a) is a diagram illustrating an example of a configuration for ensuring the conductivity of a part electrode according to the invention.

FIG. 7(b) is a diagram illustrating an example of a configuration for ensuring the conductivity of the part electrode according to the invention.

FIG. 8(a) is a diagram illustrating an example of a holder configuration for reducing a leakage current according to the invention.

FIG. 8(b) is a diagram illustrating an example of the holder configuration for reducing a leakage current according to the invention.

FIG. 9 is a diagram illustrating a result of actually measuring a leakage current in Embodiment 3.

FIG. 10 is a diagram illustrating an example of a configuration of a device including a circuit for correcting a leakage current according to the invention.

FIG. 11 is a diagram illustrating an example of a circuit configuration for eliminating a leakage current component in the Embodiment 3.

FIG. 12 is a diagram illustrating an example of an environment cell holder type secondary electron detection structure according to Embodiment 4.

FIG. 13 is a diagram illustrating an example of a method of measuring a sample GAP using an optical microscope according to Embodiment 5.

FIG. 14 is a diagram illustrating an example of a method of electrically measuring a sample GAP in the Embodiment 5.

FIG. 15(a) is a diagram illustrating an example of a method of measuring a sample GAP in a scanning electron microscope using electrons.

FIG. 15(b) is a diagram illustrating an example of the method of measuring a sample GAP in the scanning electron microscope using electrons.

FIG. 16 is a diagram illustrating an example of an operation GUI for setting an imaging condition according to the invention.

### DESCRIPTION OF EMBODIMENTS

According to the present invention, an electric field for amplifying secondary electrons is formed between a partition wall and a sample and the partition wall and the sample are spaced from each other by a distance sufficient to be free of influences from an amplification due to scattering of reflected electrons, thereby selectively detecting a secondary electron signal.

Hereinafter, embodiments of the present invention will be described in detail with reference to the drawings.

A scanning electron microscope (SEM), which is an example of a charged particle microscope, will be described below. However, it is merely an example of the present invention, and the present invention is not limited to the following embodiments. For example, the present invention may also be applied to a scanning ion microscope, a scanning transmission electron microscope, a combination of the same and sample processing apparatuses, or an analysis/inspection apparatus employing the same.

In the present specification, the term “atmospheric pressure” indicates a pressure condition equivalent to the atmospheric pressure in an atmosphere or a predetermined gas, and more particularly, in the range from about 10^5 Pa (the atmospheric pressure) to about 10^3 Pa.

In the present specification, the term “partition wall” refers to a structure that separates a non-vacuum space in a sample chamber from a vacuum surface of an electro-optical lens barrel to maintain a difference between pressures of the same and is a structure through which a charged particle beam can be transmitted or pass. For example, a partition wall refers to an orifice, a thin film, or a member including the same. Here, a thin film used as a partition wall will be referred to as a “diaphragm”, and embodiments in which diaphragms are used to separate a non-vacuum space from a vacuum space will be described. However, according to the present invention, a diaphragm may be replaced with small holes.

### Embodiment 1

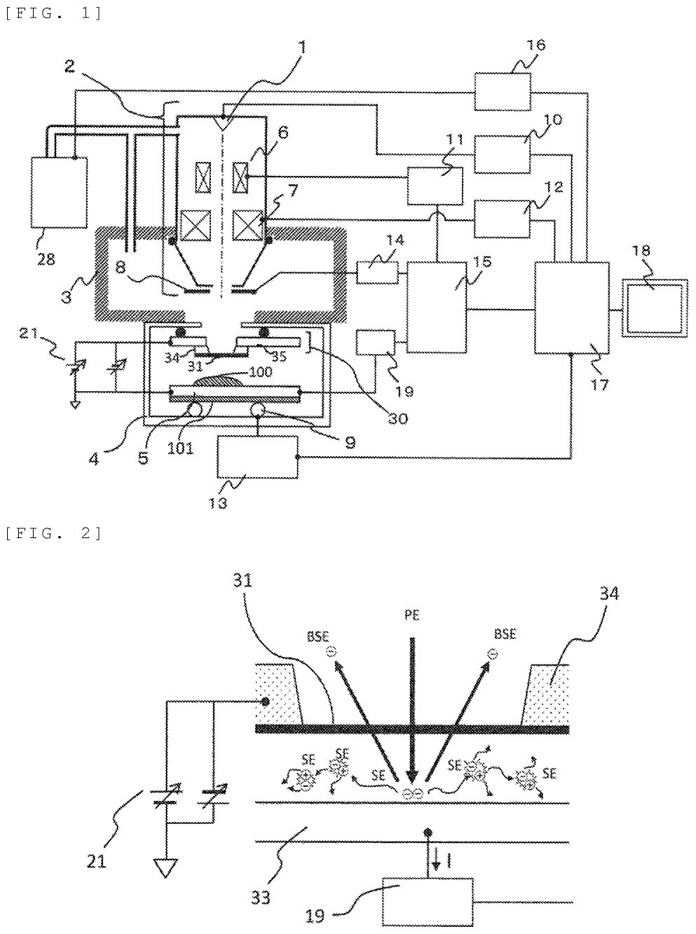

FIG. 1 illustrates a configuration of a scanning electron microscope (SEM) according to the present embodiment. The SEM is mainly composed of an electro-optical system, a stage mechanism system, a SEM control system, a signal processing system, and a SEM operating system.

The electron optical system includes an electron beam source 1 for generating an electron beam, an optical lens 7 for converging the generated electron beam to guide the converged electron beam to a lower end of an electro-optical lens barrel 2, thereby focusing the guided electron beam on a sample as a primary electron beam, and a deflector 6 for scanning primary electrons. The components are stored in the electro-optical lens barrel 2. A detector 8 for detecting emitted electrons obtained by irradiation of the primary electron beam is disposed at an end portion of the electron beam optical lens barrel 2. The detector 8 may be arranged inside or outside the electron beam optical lens barrel 2. The electro-optical lens barrel 2 may also include other lenses, electrodes, and detectors. Some of them may be different from those described above, and the configuration of the electro-optical system included in the electron beam optical lens barrel 2 is not limited thereto.

The stage mechanism system includes a sample holder 5 for holding a sample, a stage 9 that can be moved in the X-axis direction, the Y-axis direction, and the Z-axis direction, and an insulator 101 for insulating the sample holder 5 from other members. The sample holder 5 may have a configuration to which a voltage can be applied as described below. In this case, the sample holder 5 also functions as a lower electrode 33. A distance between a diaphragm holding member 35 (an upper electrode 32) holding a diaphragm 31 and the sample holder 5 (the lower electrode 33) may be adjusted by moving the stage 9 in the Z direction. Furthermore, the stage 9 may also be tiltable. The distance between the diaphragm holding member and the sample holder may be referred to as a distance between the diaphragm and the sample or a sample GAP. Although the sample GAP is adjusted by using the stage 9 in the present embodiment, a diaphragm unit 30 itself has a structure movable in the Z direction, and the sample GAP is adjusted by moving the partition wall 30. A mechanism for adjusting the sample GAP is referred to as a sample GAP adjusting mechanism.

The SEM control system includes an accelerating voltage control unit 10, a deflection signal control unit 11, an electron lens control unit 12, an XYZ stage control unit 13, an exhaust system control unit 16, and a voltage application control unit 21. The accelerating voltage control unit 10 controls an accelerating voltage of the primary electron beam by controlling each components of the electro-optical system. The deflection signal control unit 11 controls the deflector 6 to control an amount of deflection of a primary electron beam, so that the primary electron beam scans over and is irradiated onto the sample. The electron lens control unit 12 controls other electron lenses and electrodes. The XYZ stage control unit 13 controls an amount of movement of the stage 9 in accordance with a user's instruction or automatically. The exhaust system control unit 16 controls the operation of a vacuum pump and controls the degree of vacuum inside the electro-optical lens barrel 2, inside a first enclosure 3 and inside a second enclosure 4. The voltage application control unit 21 may control voltages to be applied to the diaphragm holding member 35 (the upper electrode 32) or the sample holder 5 (the lower electrode 33) by controlling a power supply capable of applying a voltage to at least one of them. In other words, in the present embodiment, the diaphragm holding member 35 functions as the upper electrode 32, and the sample holder 5 functions as the lower electrode 33. The upper electrode 32 or the lower electrode 33 is desirable to apply both a positive polar voltage and a negative polar voltage. Accordingly, a desired electric field can be formed in a space (sample GAP) between the sample and the diaphragm. Also, the upper electrode 32 and the lower electrode 33 may be provided separately from the diaphragm holding member and the sample holder, respectively. The voltage application control unit 21 may be a variable voltage power supply.

The signal processing system includes a detected signal control unit 14, an image forming unit 15, and a current-to-voltage converting unit 19. The detected signal control unit 14 performs current-voltage conversion of a signal from the detector 8 and outputs to the image forming unit 15. The image forming unit 15 generates an image based on the signal output from the detector and electron beam irradiation position information from the deflection signal control unit 11. The current-to-voltage converting unit 19 is connected at least to the sample holder 5 (the lower electrode 33), converts a current detected at least one side of the lower electrode 33 into a voltage signal, and outputs the voltage signal to the image forming unit 15. The current-to-voltage converting unit 19 is connected to both the upper electrode 32 and the lower electrode 33. The current-to-voltage converting unit 19 may be switchable so as to detect a current of either or both of the electrodes.

The SEM operating system includes an operation unit 17 for operating each units' control systems and a display unit 18 (for example, a monitor) for displaying control values and images processed by the image forming unit 15.

The control unit and the image creation unit may be constituted as a hardware on dedicated circuit boards or may be constituted by a software to be executed on a computer connected to the charged particle microscope. In case of constituting the control unit and the image forming unit as the hardware, the hardware may be implemented by integrating a plurality of calculators for executing a process on a wiring board or in a semiconductor chip or a package. In case of constituting the control unit and the image forming unit as the software, the software may be implemented by mounting a fast general-purpose CPU on a computer and executing a program for executing a desired calculation thereon. Existing equipment may be upgraded by using a recording medium having recorded thereon the program. Also, these devices, circuits, and computers are connected to one another via a wire network or a wireless network, and corresponding data is transmitted therebetween.

The electro-optical lens barrel 2 is provided so as to protrude into the interior of the first enclosure 3. The first enclosure 3 communicates with the interior of the electro-optical lens barrel 2 through a hole of a magnetic pole of an object lens at an end portion of the electro-optical lens barrel and supports the electro-optical lens barrel 2. Also, the first enclosure 3 is connected to a vacuum pump 28 via an exhaust pipe, and thus the interior of the first enclosure 3 is maintained in the vacuum state. The internal pressure of the first enclosure 3 may be the same as that of the interior of the electro-optical lens barrel or be in the vacuum state lower than the internal pressure of the electro-optical lens barrel.

The sample is placed inside the second enclosure 4 (also referred to as a sample chamber). In the example illustrated in FIG. 1, the second enclosure 4 is provided at the bottom of first enclosure as if it is supporting the first enclosure 3. However, the present invention is not limited thereto. The interior of the second enclosure 4 is non-vacuum, that is, the atmosphere or a predetermined gas atmosphere. When the interior of the second enclosure 4 is the atmosphere, the second enclosure may be opened to the atmosphere through a hole. Alternatively, to configure the interior of the second enclosure 4 to a gas atmosphere of a predetermined pressure, a gas inlet may be provided. Alternatively, if it is necessary to set the interior of the second enclosure 4 to be in the vacuum state, an exhaust port connectable to a vacuum pump may be provided in the second enclosure 4.

The interior of the electro-optical lens barrel 2 and the interior of the first enclosure 3, which are in the vacuum state, and the interior of the second enclosure 4, which is in the non-vacuum state, are separated by a partition wall (for example, the diaphragm unit 30). The diaphragm unit 30 is provided on the bottom surface of the first enclosure 3 at a position directly under the electron beam optical lens barrel 2. The partition wall unit 30 includes the diaphragm 31, a base 34 having formed thereon the diaphragm 31, and the diaphragm holding member 35 supporting the base 34. The diaphragm 31 needs to be capable of transmitting or passing therethrough a primary electron beam emitted from the lower end of the electro-optical lens barrel 2 and capable of maintaining pressure difference inside the first enclosure, which is in the vacuum state, and inside the second enclosure, which is in a non-vacuum state. The diaphragm 31 is formed of a material like a carbon material, an organic material, a metal, a silicon nitride, a silicon carbide, a silicon oxide, and the like. The diaphragm 31 is desirable to have a thickness enough for transmitting primary electrons and reflected electrons therethrough. The thickness depends on a window size and a material of the diaphragm 31, but may be about 20 nm. The diaphragm 31 may be a plurality of windows. The diaphragm 31 may have a shape like a rectangular shape rather than a square shape. The shape doesn't matter. Also, the conductivity of the diaphragm 31 itself is not important. In the present embodiment described below, for example, the diaphragm unit 30 with a SiN film having a thickness of about 20 μm and a window size of about 250 μm is used. However, the present invention is not limited by the size of the diaphragm.

The base 34 is a member formed of silicon or a metal, for example. The diaphragm holding member 35 is a member for installing the diaphragm 31 and the base 34 to separate the first enclosure 3 and the second enclosure 4 from each other. The diaphragm holding member 35 may have a configuration to which a voltage can be applied as described below. In this case, the diaphragm holding member 35 also functions as the upper electrode 32.

The primary electron beam passes through the diaphragm unit 30 and ultimately reaches a sample 100 mounted on the sample holder 5 (the lower electrode 33). When the primary electron beam is irradiated on the sample 100, secondary electrons and reflected electrons are emitted from the sample. According to the principle described below with reference to FIG. 2, secondary electrons can be detected as a current flowing through the lower electrode 33 in the present embodiment. A signal from the current-to-voltage converting unit 19 connected to the lower electrode 33 is detected by the image forming unit 15 in synchronization with the deflector 6, and thus a substrate current image is formed. The substrate current image is displayed on the display unit 18 through the operation unit 17.

The following is a method of selectively detecting secondary electrons in a state where a sample is installed in space under the atmospheric pressure, by using the device illustrated in FIG. 1.

Hereinafter, in the present specification, a current amount of a lower electrode will be referred to as a substrate current amount or a lower electrode current image, measurement of a current amount of the lower electrode will be referred to as measurement of a substrate current or measurement of a lower electrode current, and an image formed by the control unit by using a measured substrate current will be referred to as a substrate current image or a lower electrode image. Also, in the present specification, a distance between a diaphragm and a sample is referred to as a sample GAP. Here, the distance between the diaphragm and the sample refers to a distance between a surface of the diaphragm and a surface of the sample or a distance between the surface of the diaphragm and a surface of a sample holder.

There are many gas molecules in the atmospheric pressure and, when an electron with energy collides with a gas molecule, amplification phenomenon occurs in which one electron and one ion are generated. Without an electric field, electrons and ions generated by a collision disappear. However, when an electric field is applied, electrons and ions generated by a collision are rapidly amplified. The same phenomenon occurs for photons. An amplification amount of the electrons generated by the ionization collision by the electrons is represented by e^{αχ}, and the more the ionization collisions of electrons occur, the greater the amplification amount becomes. The inventors of the present invention have devised a method of selectively detecting secondary electrons having low energy using the amplification phenomenon.

The principle of amplifying and detecting secondary electrons will be described with reference to FIG. 2. FIG. 2 denotes a primary electron beam as PE, a secondary electron as SE, reflected electrons as BSE, and an electron/ion current induced by amplified secondary electrons as I. Also, in FIG. 2, a sample is omitted.

When the primary electron beam is irradiated on the sample, secondary electrons and reflected electrons are emitted from the surface of the sample. The secondary electrons are amplified through ionization collision with gas molecules existing in a non-vacuum space between the diaphragm 31 and the lower electrode 33. More specifically, from the ionization collision with the gas molecules, positive ions and electrons are generated, and the secondary electrons lose their energy. Next, the generated positive ions and electrons collide with different gas molecules, respectively. As a result, positive ions and electrons are generated again. This process is repeated and the secondary electrons are amplified. In the present embodiment, the voltage application control unit 21 may form an electric field in the non-vacuum space between the diaphragm 31 and the lower electrode 33, supply energy for amplification to secondary electrons thereby, and increase the total number of ionization collisions, thereby amplifying signal components originated from secondary electrons.

The amplified electrons or ions are absorbed by the upper electrode 32 or the lower electrode 33. FIG. 2 illustrates an example of a current detection by the lower electrode. In the case of FIG. 2, a positive voltage is applied to the upper electrode by the voltage application control unit 21. However, it seems that, at the lower electrode 33, the positive ions and the electrons generated by the ionization collision are mixed with each other and absorbed.

At this time, the reflected electrons are also amplified by the ionization collision with the gas molecules in the same regard. However, since the energy of the reflected electrons is sufficiently higher than that of the secondary electrons, when the sample GAP is small, the reflected electrons pass through the diaphragm 31 before repeated amplification due to ionization collision occurs. Therefore, an increment of an amplified current due to the secondary electrons may be selectively detected with a sample GAP causing no or a small number of ionization collisions of reflected electrons. The sample GAP may be adjusted by controlling the stage 9.

The number of collisions with gas molecules may be determined by sample GAP (x)/mean free path of electrons (X) =average number of scatterings (y), and the average total amplification amount of the sample GAP may be simply indicated as γe^{α(E)x}. Based on the relationship, a current amount of reflected electrons and secondary electrons amplified by an electric field may be expressed as follows.

I_{BSE}=ηγ_{BSE}e^{α(E)x} [Equation 1]

I_{SE}=δγ_{SE}e^{α(E)x} [Equation 2]

Here, η and δ denote the electron emission rate of electrons emitted from a sample when a primary electron beam is irradiated. η denotes the electron emission rate of reflected electrons, and δ denotes the electron emission rate of secondary electrons. γ_{SE} and γ_{BSE} denote the average numbers of scatterings, x denotes the sample GAP, and α(E) denotes an electron amplification amount changed by an electric field. In the present embodiment, the range of the electron emission rate η is from 0.01 to 0.6, and the range of the electron emission rate δ is from 0.1 to 1. Since electrons are amplified by a collision between gas molecules and electrons, when reflected electrons pass through the diaphragm 31 without being scattered and reach the vacuum state, γ_{BSE}=0 is valid, and thus signal components of I_{BSE} are not detected at the lower electrode . Also, since secondary electrons lose energy through one collision with air molecules, the average number of scatterings of secondary electrons is γ_{SE}=1.

According to the two equations above, secondary electrons can be selectively detected at the lower electrode as long as γ_{BSE}<γ_{SE} is valid. Also, in reality, when γ_{BSE} is close to γ_{SE}, the current depends on the electron emission rates η and δ, but typically, η<δ is valid. Therefore, it can be said that secondary electrons can be selectively detected when γ_{BSE}<γ_{SE} is valid. Here, when the sample GAP is reduced, γ_{BSE} can be reduced, and thus the sample GAP may be adjusted to make γ_{BSE} greater than γ_{SE}.

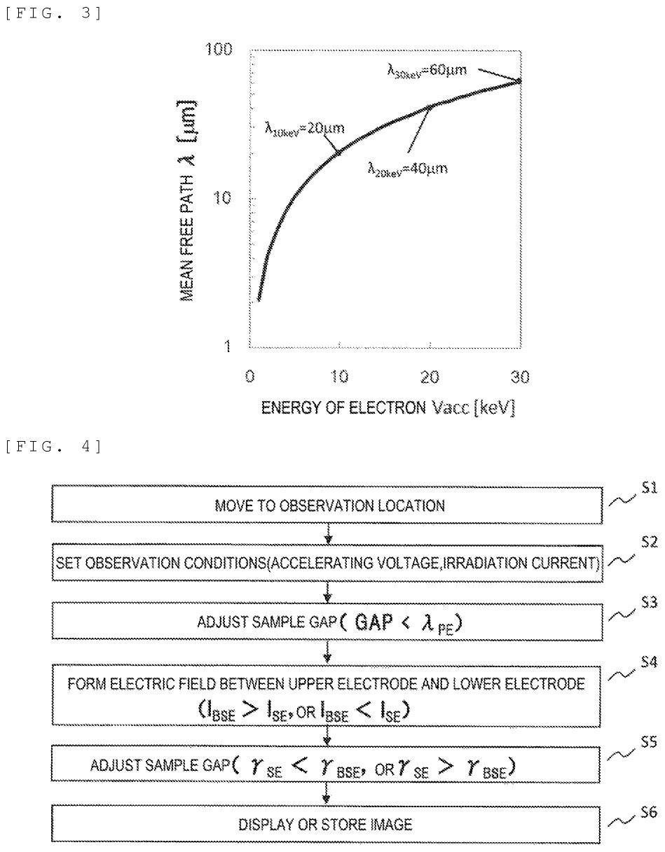

FIG. 3 illustrates a relationship between an accelerating voltage of a primary electron beam and the mean free path in an atmospheric pressure space, based on a relationship between mean free path at respective accelerating voltages according to a theoretical equation. The vertical axis indicates the mean free path, whereas the horizontal axis indicates the energy of accelerating electrons. It may be observed that the mean free path amount of electrons increases as the accelerating voltage increases. For example, when the acceleration voltage is 10 keV, the mean free path is 20 μm. When the acceleration voltage is 20 keV, the mean free path is 40 μm. When the acceleration voltage is 30 keV, the mean free path is 60 μm. Since the energy of reflected electrons is determined by the accelerating voltage of the primary electron beam, secondary electron can be selectively amplified and detected by adjusting the sample GAP so as to satisfy γ_{BSE}<γ_{SE} according to the accelerating voltage.

FIG. 4 illustrates a flow of acquisition of a substrate current image having desired information through selective detection of emitted electrons. First, the stage mechanism system shifts a visual field to an observation position of the sample (S1). An acceleration voltage and an irradiation current, which are basic observation conditions, are set through a SEM manipulating operation (S2).

Next, the sample GAP is adjusted according to the mean free path of the primary electron beam in gases present in the non-vacuum space in which the sample is loaded (S3). In order to obtain the mean free path, the acceleration voltage set in the step S2 as the acceleration voltage is used as a parameter. In this step, the sample GAP is set to be smaller than the mean free path λ_{PE} of the primary electron beam. The mean free path may be calculated automatically by a simulation or the like depending on gas pressure and type of gas in the sample room or may be calculated by the user. The sample GAP may be adjusted by moving the sample in the Z direction through the stage mechanism system. When this step is performed, the primary electron beam is irradiated to the sample.

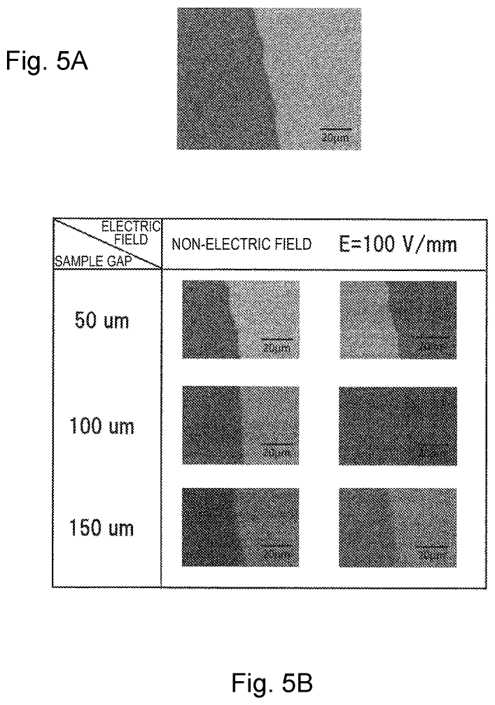

Next, an electric field is formed between the upper electrode and the lower electrode by the voltage application control unit 21 (S4). At this time, a voltage value is adjusted depending on whether desired information is a reflected electron image or a secondary electron image. In order to obtain a reflected electron image, the voltage value is adjusted so as to satisfy I_{BSE}>I_{SE}. In order to obtain a secondary electron image, the voltage value is adjusted so as to satisfy I_{BSE}<I_{SE}. In fact, as described below with reference to FIG. 5, when a voltage is not applied, an image largely having reflected electrons components can be obtained. Therefore, in order to obtain the secondary electron image, an electric field may be applied. When an applied voltage increases, as described below with reference to FIG. 9, a leakage current from the upper electrode to the lower electrode increases. Therefore, it is desirable to set the applied voltage, such that that a leakage current becomes smaller than the amount of a current caused by amplified secondary electrons flowing into the substrate. The value of the applied voltage may be set to a predetermined value.

When desired information cannot be obtained at this stage, the sample GAP is adjusted again (S5). In this step, the sample GAP is adjusted so as to satisfy γ_{BSE}<γ_{SE}. The smaller the sample GAP is, the smaller γ_{BSE} is. Therefore, when the secondary electron image cannot be obtained after the step S4 is performed, the sample stage may be brought closer to the diaphragm.

A current flowing in the substrate through the sample is converted into a signal voltage by the current-to-voltage converting unit 19, and the signal voltage sampled in synchronization with a deflection signal of the deflector 6 is converted to image data by the image forming unit 15 and is displayed on the display unit or stored (S6).

Therefore, in reality, the sample GAP may be adjusted by repeating the steps S5 and S6 and checking images until a desired image is obtained.

Referring to FIGS. 5(a) and 5(b), a difference between images obtained when a sample GAP and an electric field are adjusted will be described. In order to evaluate the selectivity of secondary electrons according to the present embodiment, a test sample having a SiC region and an Au region (SiC/Au substrate) was used. The reason for using SiC/Au for the test sample was that, at the accelerating voltage of 30 kV, the rate of emitting reflected electrons is higher in Au than in SiC and the rate of emitting secondary electron is higher in SiC.

FIG. 5(a) is an atmospheric pressure SEM image of a SiC/Au substrate obtained by a reflection electron detector 8 provided at the lower portion of the electro-optical lens barrel 2. It can be seen that, since the contrast of the Au region is brighter than that of the SiC region, the image is based on reflected electrons.

FIG. 5(b) illustrates a result of verifying a relationship between the electric field formed between the sample and the diaphragm and the sample GAP. FIG. 5(b) compares a case in which an electric field of 100 V/μm is formed between the sample and the diaphragm to a case without the electric field. Test conditions are when sample GAP is 50 μm, 100 μm, and 150 μm at an accelerating voltage of 30 kV and an irradiated current of 2 nA, where substrate current images obtained without no electric field were compared to substrate current images obtained with electric fields. A substrate current signal becomes a contrast that inverted a difference between electron emitting rates. Therefore, in FIG. 5(b), the substrate current signal was inverted and made as an image. When the substrate current signal image is an image formed from an amplified portion of reflected electrons, the Au region becomes brighter than the SiC region. On the other hand, when the substrate current signal image is an image formed from an amplified portion of secondary electrons, the SiC region becomes brighter than the Au region.

In FIG. 5(b), in the substrate current image obtained without the electric field, the Au region with higher emitting rate of reflected electrons is brighter, and the SiC region is darker. In case without the electric field, secondary electrons are not amplified and are absorbed back into the sample. Since electrons emitted from the sample are only the reflected electrons, a contrast due to reflected electrons is formed. There was also the same tended result for each sample GAP. When an electric field of 100 V/μm was applied to the sample GAP of 50 μm, SiC became bright and Au became dark, and the contrast was opposite to that of the reflection electron image (FIG. 5(a)). The amount of a substrate current increases because emitted electrons returning to the lower electrode are positive ions generated by an ionization collision. Therefore, it can be seen that amplified signals by secondary electrons are selectively retrieved. Also, in the case with the electric field of 100 V/μm, similar phenomena could be observed with the sample GAPs of 50 μm and 100 μm. However, when the sample GAP was 150 μtm, the amplified signal component originating from reflected electrons increases as the average number of scatterings of reflected electrons increases, and thus the substrate current image obtained therefrom becomes similar to the reflected electron image.

From these results, it was confirmed that amplification due to the ionization collision originated from secondary electron signals could be measured according to sample gaps.

When the sample GAP exceeds 100 μm, the scattering amount of the primary electron beam also increases, and thus resolution is deteriorated. Therefore, the sample GAP with guaranteed resolution may be x≤3λ_{PE}. Also, the range of the sample GAP for selectively detecting secondary electrons is x≤3λ_{BSE}. λ_{BSE} refers to the mean free path of reflected electrons in gases present in a non-vacuum space of a space in which the sample is loaded. However, the value of λ_{BSE} varies depending on an electric field applied to the sample GAP. Also, in the present embodiment, although a threshold value is set to be three times λ_{BSE}, an actual threshold value depends on a sample material and a device configuration. However, even in such a case, the threshold value is also determined according to a relationship between λ_{BSE} and λ_{SE}. Also, the voltage applied to the sample GAP maybe less than or equal to 3 kV/mm, which is the insulation breakdown field of the air. For example, the voltage applied to the upper electrode is 150V or less when the sample GAP is 50 μm. Furthermore, according to the present embodiment, emitted electrons to be detected may be selectively controlled by adjusting the sample GAP. When a distance to be traveled by emitted electrons (the sample GAP) is long, reflected electrons with high energy repeat many ionization collisions, thereby generating more electrons and ions than the secondary electrons. Therefore, a substrate current is largely overlapped by signals amplified by the reflected electrons. In other words, the current image becomes a current image due to secondary electrons in the range of x≤3λ_{BSE} and becomes a current image largely including reflected electron components in the range of x≥3λ_{BSE}.

As described above, according to the present embodiment, the sample GAP is adjusted under the atmospheric pressure to selectively induce an amplification phenomenon due to ionization collision of secondary electrons, and thus an image including information originated from the secondary electrons may be obtained.

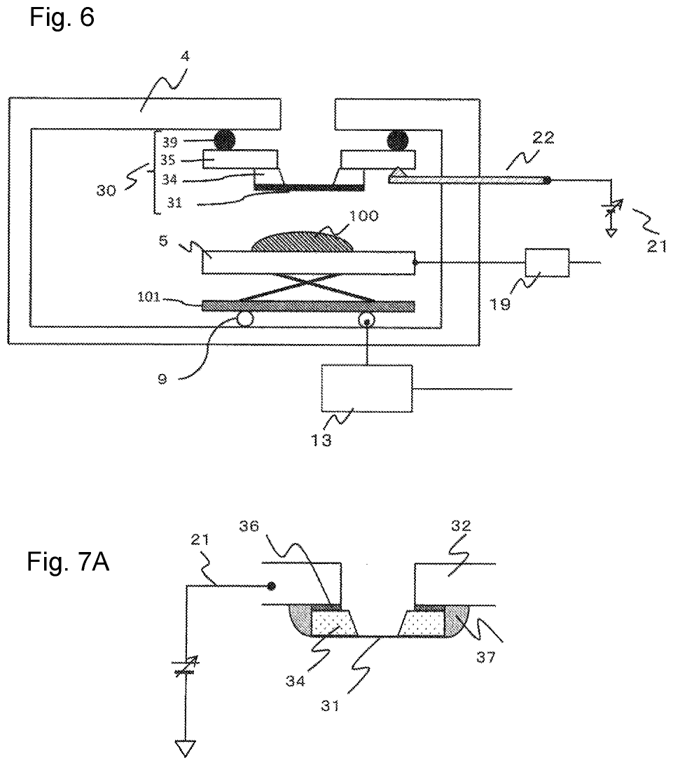

FIG. 6 is an overview of the interior of the second enclosure, which maintains the sample and the sample stand under the atmospheric pressure. Also, in FIG. 6, portions identical to those illustrated in FIG. 1 other than portions around the second enclosure 4 are omitted. However, the electron beam optical lens barrel 2 as illustrated in FIG. 1 is provided at the upper end portion of the second enclosure 4. As described above with reference to FIG. 1, the diaphragm holding member 35 functions as the upper electrode 32, and the sample holder 5 functions as the lower electrode 33.

FIG. 6 illustrates that the voltage application unit 22 controlled by the voltage application control unit 21 is applying voltage to the upper electrode 32. For example, the voltage application unit 22 is a metal rod having a spring structure at a leading end. The voltage application unit 22 contacts the upper electrode via the leaf spring structure and applies voltage to the upper electrode. FIG. 6 illustrates a structure in which the voltage application unit 22 is inserted through an insertion portion of the wall of the second enclosure and is connected to the voltage application control unit 21 outside the second enclosure 4. The voltage application to the voltage application unit 22 may be performed from the outside by using a terminal of the sample stage 5. Also, the second enclosure 4 may be provided with a terminal connected to the sample holder 5. Also, the voltage application unit 22 may be omitted, and the voltage application control unit 21 may be directly connected to the upper electrode 32. However, if the voltage application unit 22 is directly connected to the upper electrode, when the diaphragm 31 is damaged, it is necessary to detach a cable when the diaphragm holding member, which is the upper electrode, is separated from a device. Here, as illustrated in FIG. 6, by connecting the voltage application control unit 21 via the voltage application unit 22, it is sufficient to disconnect connection to the voltage application unit 22 when a diaphragm is to be exchanged. Therefore, the operation efficiency is improved.

The current-to-voltage converting unit 19 is connected to the lower electrode 33, and current absorbed to the lower electrode 33 is converted into voltage and output to the image forming unit 15. The sample 100 is placed on the sample holder 5, which is the lower electrode 33.

In the present embodiment, a voltage is applied to the upper electrode 32, but a voltage may be applied to the lower electrode 33. In this case, the current-to-voltage converting unit 19 connected to the lower electrode 33 has a circuit structure electrically floated by the voltage application control unit 21, and the upper electrode 32 is grounded.

The space in which the sample is installed is kept as the atmospheric pressure by a sealing member 39, such as an O-ring between the upper electrode 32 and the second enclosure 4. The sample GAP can be adjusted by moving the stage 9 in the Z-axis direction.

In the present embodiment, the environment surrounding the second enclosure 4 is the atmosphere, but the gas inside the second enclosure maybe gas other than the air, for example, He and Ar. In particular, He has the characteristic that the mean free path is long because the element number and density are small compared to other gas molecules. Therefore, by including He in the gas inside the second enclosure, the mean free path becomes long, thereby facilitating the adjustment of the sample GAP. Also, the present invention is not necessarily limited to the atmospheric pressure, and the applicable range of vacuum is from 1330 Pa to the atmospheric pressure. As the pressure drops, the density of molecules in gas decreases, and thus the probability of collision between the air molecules and electrons decreases. Therefore, the mean free path increases. Even under low vacuum, secondary electron can be selectively detected by adjusting the sample GAP, such that γ_{SE} is greater than γ_{BSE}. In reality, for example, the sample GAP may be a sample GAP (x≤3π_{BSE}) up to three times the mean free path of reflected electrons.

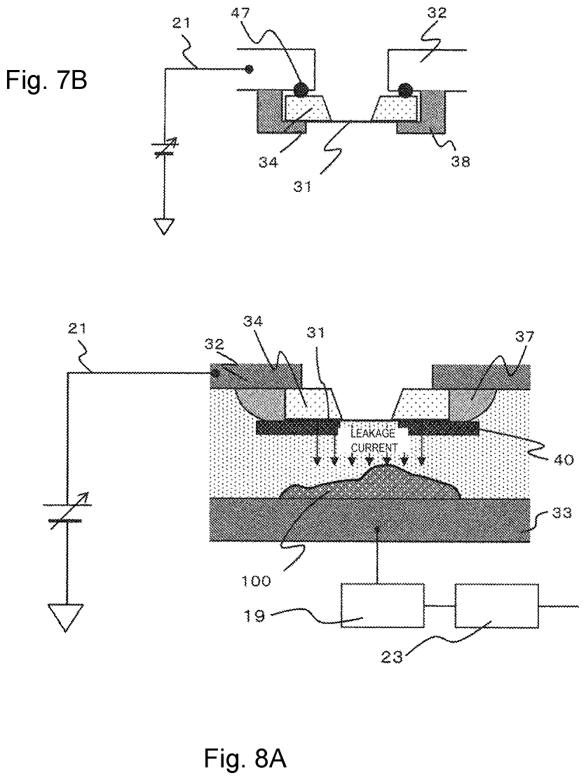

As illustrated in FIG. 6, in order to form a desired electric field between the diaphragm 31 and the sample by the voltage applied to the upper electrode 32, the upper electrode 32 and the diaphragm 31 need to be electrically connected to each other. FIG. 7 illustrates a configuration example for securing the conductivity of the upper electrode 32 and the diaphragm 31.

An example thereof is illustrated in FIG. 7(a). The diaphragm unit includes the electron-transmissible diaphragm 31 formed on the base and the upper electrode 32 formed of a metal for fixing the diaphragm. An opening for passing the primary electron beam and reflected electrons therethrough is provided at the center portion of the upper electrode 32, wherein the opening is provided to have the center line aligned to that of a SiN opening of the diaphragm 31. The base 34 having formed thereon the diaphragm 31 and the upper electrode 32 are fixed by using an adhesive 36. At this time, both the opening of the upper electrode 32 and the SiN opening of the diaphragm 31 are provided to not to interfere the primary electron beam and the reflected electrons. Also, the adhesive 36 may or may not be conductive.

When the conductivity of the SiN opening of the diaphragm 31, through which primary electrons and reflected electrons are transmitted, is not sufficient, negative charges gradually accumulate as electrons are transmitted. As a result, the diaphragm 31 is negatively electrified, and thus there may be an influence on the trajectory of the primary electron beam or noise components of a leakage current or the like generated between the diaphragm and the sample may increase. Therefore, the upper electrode 32 and the diaphragm 31 are connected to each other via a conductive material 37 to ensure the conductivity between the upper electrode 32 and the diaphragm 31 and remove negative charges accumulated in the diaphragm 31. As the conductive material 37, silver paste, carbon paste, and Cu tape may be used, for example. When the base 34 is conductive, the adhesive 36 may also serve as the conductive material 37.

FIG. 7(b) illustrates an example in which the diaphragm 31 and the base 34 are fixed to the upper electrode 32 by using a conductive cap 38. Instead of the adhesive of FIG. 7(a) made of a conductive material, the base may be attached to the upper electrode 32 by a cap (the conductive cap 38) made of a conductive material as illustrated in FIG. 7(b). Furthermore, a sealing member 47, such as an O-ring, may be provided between the base 34 and the upper electrode 32. The conductive cap 38 is attachable and detachable from the diaphragm and the upper electrode. In the example illustrated FIG. 7(b), as illustrated in FIG. 6, the upper electrode 32 is stuck to the second enclosure 4 through a sealing member 39, such as an O-ring, thereby separating the interior of the second enclosure 4 from the vacuum space inside the charged particle optical lens barrel. In FIG. 7(a), the diaphragm is fixed to the upper electrode by an adhesive, and thus the upper electrode needs to be replaced every time the diaphragm is replaced. In contrast, as illustrated in FIG. 7(b), as the diaphragm is fixed by a detachable conductive cap, it is not necessary to replace the upper electrode itself, which is a diaphragm holding member, and thus the diaphragm 31 and the base 34 can be separated from the upper electrode and replaced by detaching the conductive cap. Therefore, the upper electrode may be continuously used.

As described above, according to the present embodiment, secondary electrons can be selectively obtained at the voltage application unit under the atmospheric pressure. It is difficult to distinguish and detect secondary electrons and reflected electrons at the upper electrode when trying to detect secondary electrons at the upper electrode, because the reflected electrons are also incident to the upper electrode. Here, according to the method of detecting amplified secondary electrons by measuring the substrate current at the lower electrode as in the present embodiment, secondary electrons and reflected electrons can be distinguished and detected according to the electric field formed in the sample GAP and the size of the sample GAP.

### Embodiment 2

In the above-stated embodiment, when a voltage is applied to the upper electrode by the voltage application control unit, a leakage current flowing from the upper electrode to the lower electrode may occur. In the present embodiment, a method of reducing noise due to such a leakage current will be described. Hereinafter, descriptions identical to those of the Embodiment 1 will be omitted.

In order to selectively obtain secondary electrons, it is necessary to apply voltage from several V to dozens of V to the upper electrode or the lower electrode in the state where the sample GAP is from dozens of μm to hundreds of μm. For example, when the sample GAP is 50 μm and the voltage is 5V, an electric field of about 100 V/mm is generated. Then, as indicated by the arrow in FIG. 9, a leakage current from the upper electrode to the lower electrode is generated via the molecules in the atmosphere. When the order of the leakage current becomes more than that of a signal of several nA measured under an electron beam irradiation, a signal due to electrons having a surface morphology cannot be normally measured. Therefore, in the present embodiment, a method of reducing a leakage current by inserting an insulating material between the diaphragm holder and the lower electrode will be described.

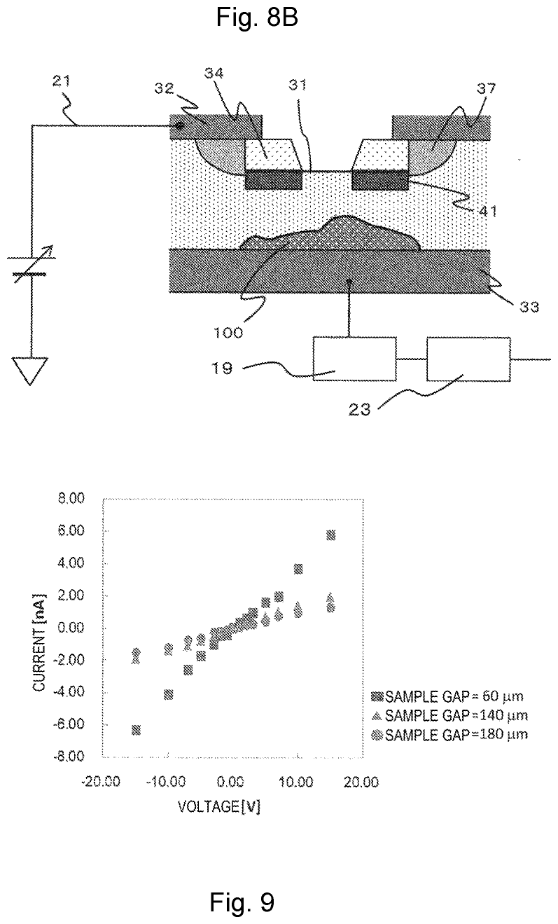

FIG. 8(a) illustrates a configuration of a sample holder for reducing a leakage current. An insulating member 40 is provided between the diaphragm 31 and the sample 100. In other words, the insulating member 40 is provided on the surface of the diaphragm 31 so as to face the sample. Also, a hole is formed at the central portion of an insulating material (the opening of the base 34), and thus the primary electron beam and reflected electron can pass through. The insulating member 40 is provided on the outer periphery of the diaphragm 31 as not to overlap the SiN opening of the diaphragm 31. Therefore, the resistance of the part between the upper electrode 32 and the lower electrode 33 is increased, thereby reducing a leakage current flowing through the lower electrode 33. Here, the insulating member 40 may be a cellophane tape or a polyimide tape. Alternatively, as illustrated in FIG. 8(b), an insulating film 41, such as a resist and a PIQ film, may be formed on the diaphragm 31 itself.

FIG. 9 illustrates a result of measuring a leakage current to the lower electrode 33 when a voltage is applied to the upper electrode 32. FIG. 9 illustrates a result of an actual measurement in a state where one layer of a polyimide tape having a thickness of about 50 μm was attached to the diaphragm holder 30 as illustrated in FIG. 8(a). The vertical axis represents an amount of a leakage current, and the horizontal axis represents voltage applied to the upper electrode, and measurements were made for each sample GAP. Based on the results, it was found that there was a leakage current component that could not be removed only by the polyimide tape, and the amount of the leakage current flowing through the lower electrode 33 was proportional to the applied voltage and the sample GAP.

In the present embodiment, a current measuring-processing unit 23 is provided for current signals flowing in the lower electrode, since a leakage current becomes the background for forming a substrate current image.

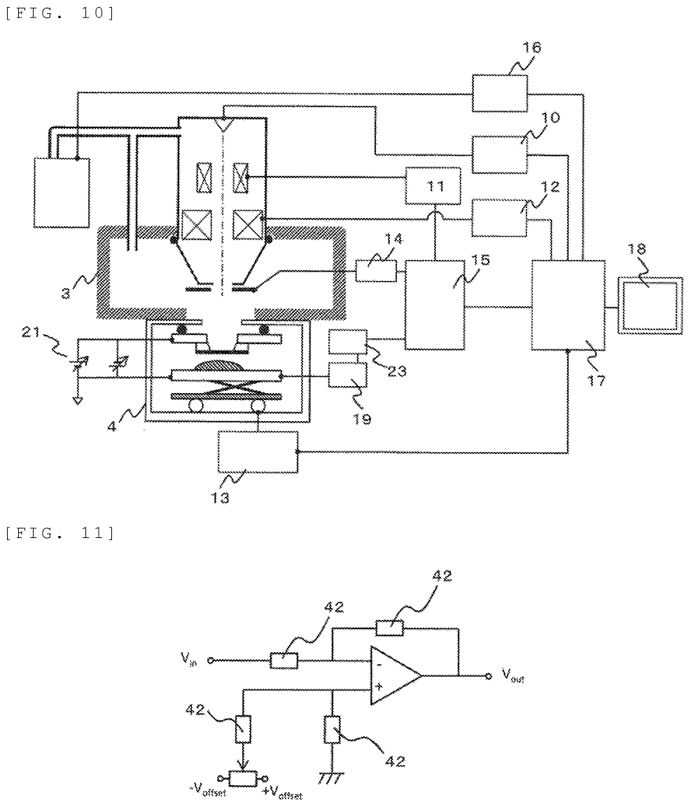

FIG. 10 illustrates the overall configuration of a device according to the present embodiment. Other than the current measuring-processing unit 23, the device is identical to that of FIG. 1, and thus descriptions thereof are omitted. The current measuring-processing unit 23 is an adjusting circuit that measures a leakage current and offsets as much as the leakage current. The amount of a leakage current used for the offset maybe measured for each observation. For example, when a sample is replaced, the leakage current to be used for the offset in case where working distance (sample GAP) is changed may be re-measured. In other words, by irradiating a charged particle beam to the sample while an electric field is being applied between the upper electrode and the lower electrode, the amount of the leakage current used for the offset is subtracted from the amount of current flowing in the lower electrode. When the amount of the leakage current to be used for the offset is set, the current measuring-processing unit 23 subtracts the set leak current amount every time (that is, every pixel) from a current flowing to the lower electrode 33, an offset-processed current signal is output to the image forming unit 15, and an image is formed.

A method of measuring the leakage current as the offset will be described. First, voltage is applied to the upper electrode 32 from the voltage application control unit 21 in a state where the primary electron beam is not irradiated, and an electric field is generated. At this time, since current flowing in the lower electrode 33 is the leakage current, the amount thereof is measured. The actually measured amount of the leakage current is input to and stored in the current measuring-processing unit 23 as an offset amount for measuring a lower electrode current. However, when the electric field is strong, the leakage current is not stable, and thus it becomes difficult to select a correction value. Therefore, the correctable range of the intensity of an electric field may be up to 1 V/μm.

FIG. 11 illustrates a specific example of an offset adjusting circuit used as the current measuring-processing unit 23. This circuit is merely an example, and any circuit may be used as long as the circuit is capable of adjusting an offset and includes a signal amplification circuit. This circuit may be installed either inside or outside the second enclosure. There is also a method of implementing the current measuring-processing unit 23 as software, wherein an offset adjusting circuit is not used. In this case, for example, a digital offset portion may be subtracted at the image forming unit 15 from a signal input to the image forming unit 15 after the signal is converted by the current-to-voltage converting unit 19. In other words, the image forming unit 15 may adjust the brightness per pixel.

As described above, according to the present embodiment, noises due to a leakage current can be reduced, and thus the image quality of a secondary electron image under the atmospheric pressure may be improved.

### Embodiment 3

In the present embodiment, a configuration of a SEM in which a capsule-shaped sample cell is placed in a vacuum-exhausted case and secondary electrons from the sample under the atmospheric pressure can be selected and detected will be described. This sample cell has a space in which a sample can be loaded, and the internal atmosphere of the sample cell can be set to an arbitrary type of gas and a desired pressure . In the present embodiment, the internal atmosphere of the sample cell is the atmosphere.

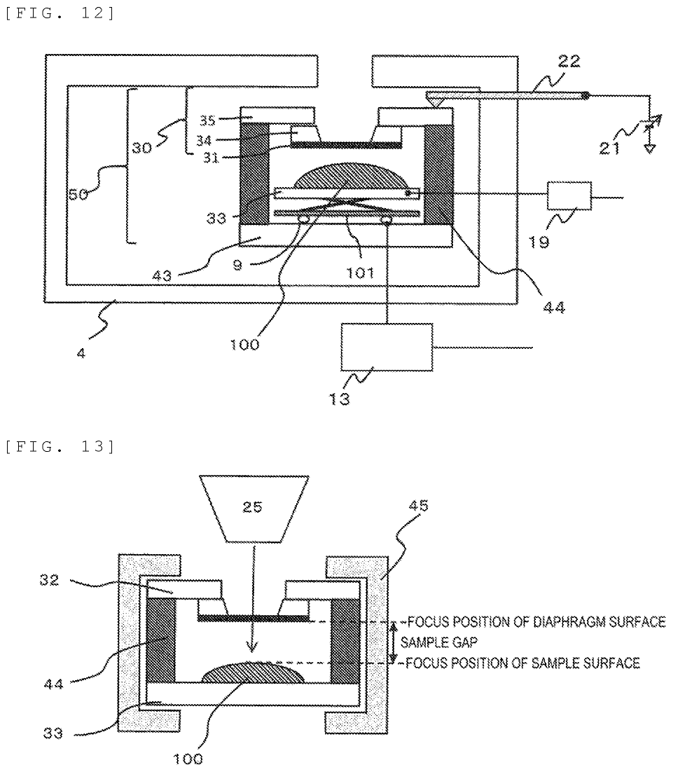

FIG. 12 is a schematic view of the interior of the second enclosure 4 provided with the sample cell. Since the exterior of the second enclosure is the same as that in FIG. 1, the detailed description thereof will be omitted. A sample cell 50 includes the upper electrode 32, the lower electrode 33, and the sealing member 44. The sealing member 44 constitutes the sidewall of the sample cell 50, seals the upper electrode 32 and the lower electrode 33, and maintains an atmospheric pressure space in a vacuum space. The upper electrode is stuck with the diaphragm unit 30. In the present embodiment, the upper electrode 32 serves as a cap of the sample cell. The sample 100 is placed on the lower electrode inside the sample cell. In other words, the sample 100 is placed between the upper electrode 32 and the diaphragm unit 30 and the lower electrode 33.

Also, the voltage application unit 22 controlled by the voltage application control unit 21 is installed so as to be able to contact the upper electrode 32 and applies voltage to the upper electrode 32. Voltage may be applied to the lower electrode 33 instead of applying the voltage to the upper electrode 32 as described above in the above-described embodiment. The current-to-voltage converting unit 19 is connected to the lower electrode 33. At this time, the sealing member 44 between the lower electrode 33 and the upper electrode should maintain the atmospheric pressure space and be electrically insulated. Therefore, at least a portion of the sealing member 44 is formed of an electrically insulating material. The insulating material may be, for example, an O-ring, a gel sheet, or an adhesive. Alternatively, the sealing member 44 maybe entirely made of an insulating material. This insulating material may also be used as a spacer for securing or adjusting the sample GAP.

Also, in case of adjusting the sample GAP, the height of the sealing member 44 may be adjusted or a stage mechanism provided in the sample cell may be used. The operation of the stage mechanism is controlled by an XYZ stage controller which is movable in the X-axis direction, the Y-axis direction, and the Z-axis direction. In the present embodiment, the XYZ stage 9 is provided in the capsule. The stage is electrically insulated from the lower electrode 33 by an insulator 101.

By using the capsule-shaped sample cell according to the present embodiment, voltage can be applied between the upper electrode 32 and the lower electrode 33, and the sample GAP between the sample 100 and the diaphragm 31 can be adjusted. Therefore, even in a vacuum-exhausted enclosure, a secondary electron image can be obtained while the sample is installed in the atmospheric pressure space.

### Embodiment 4

In the present embodiment, an inter-electrode distance control unit for measuring a sample GAP will be described. Hereinafter, descriptions identical to those of the Embodiment 1 will be omitted.

As described above, in the present invention, it is important to control the sample GAP. The sample GAP may be narrowed by accurately measuring the height of the sample GAP. Therefore, the scattering of primary electrons can be reduced under the atmospheric pressure, thereby improving resolution. In addition, since a signal component of an amplified portion of an ionization scattering by reflected electrons decreases, the selectivity of secondary electrons may be improved, and a clearer contrast that reflects a surface morphology to abase current image can be obtained.

FIG. 13 illustrates a schematic view of a sample GAP measurement using an optical microscope. In a state where the sample is provided in the holder, the upper electrode 32, the sealing member 44, and the lower electrode 33 are fixed as if they are picked by a fixing jig 45, thereby forming a sealed space. At this time, the sample 100 is installed, such that a portion to be observed is located immediately below a SiN opening. When the XYZ stage 9 is embedded in the holder, the XYZ stage may be adjusted to locate a portion to be observed of the sample directly below. First, the optical microscope is adjusted as to focus positions to each of a sample surface and a surface of a SiN diaphragm, a difference between focus positions of the sample surface and the diaphragm surface are measured, and the difference is set as the sample GAP. The sample GAP may be adjusted by selecting and using various kinds of sealing members 44 having different thicknesses or adjusting the fixing force of the fixing jig 45 to adjust the sealing member 44 within the crushing margin range. The method illustrated in FIG. 13 is effective in case of using an environmental cell type holder as illustrated in FIG. 12.

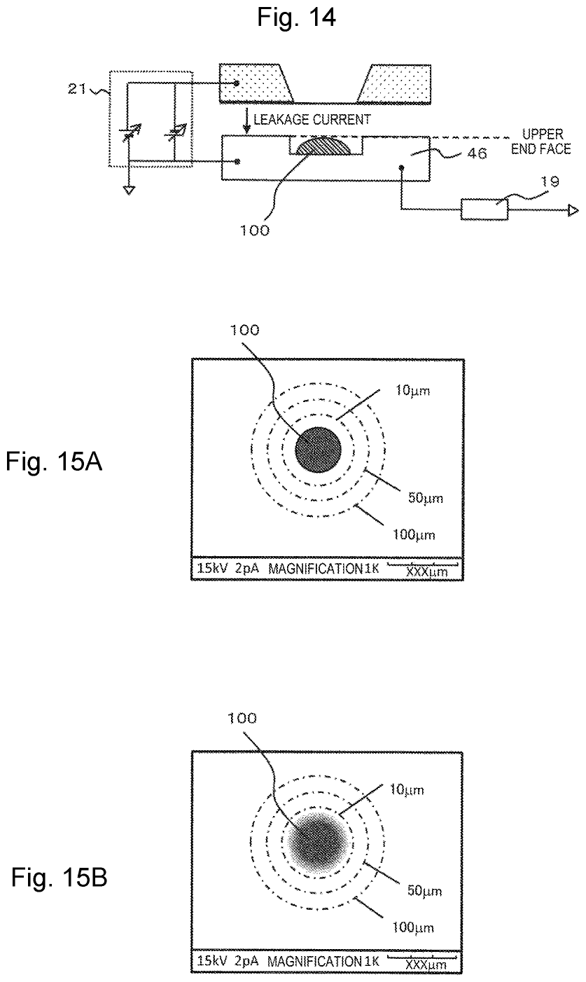

FIG. 14 illustrates a method of measuring the sample GAP using a leakage current as another example. In the method illustrated in FIG. 14, a surface of the sample 100 to be observed is provided on the top surface of a height adjusting sample stand 46 having a structure in which a portion where the sample 100 is provided is a step lower from the upper end. Considering the influence on an electric field by installing the sample, it may be desirable to align the surface of the height adjusting sample stand 46 with the surface of the sample 100. Specifically, the top surface of the height adjusting sample stand 46 and the surface of the sample 100 maybe aligned based on a focus point of the optical microscope or the like. At this time, the voltage application control unit 21 applies a standard application voltage, and a leakage current flowing at this time is measured. The sample GAP is obtained from a magnitude of leakage current measured based on a relationship between a leakage current and a sample GAP obtained in advance. A constant standard application voltage is set for each equipment in advance. The relationship between the leakage current and the sample GAP is measured in advance and stored in a database or the like.

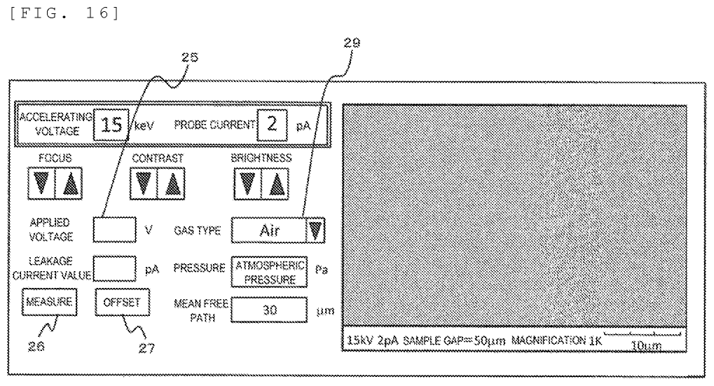

FIG. 15 illustrates a method of measuring the sample GAP in a SEM using electrons as another example. In the atmospheric pressure space, a flare amount increases due to collisions with gas molecules, and the diameter of a beam increases until the beam reaches a sample. In the vacuum state, since there are few gas molecules, a beam has a diameter with little flare. When the sample GAP is long, the number of collisions between electrons and gas molecules increases, and thus the flare amount increases. Therefore, the sample GAP may be measured by using the flare amount as a parameter.

In FIG. 15, as a standard sample for measuring the sample GAP, a sample made of heavy metal, such as Au, Cu, and Pt, on a thin film formed on Si or Al is used. The standard sample is placed at an arbitrary position of the sample holder 5.

FIG. 15(a) is a schematic view of a display unit in which a sample for measuring the flare amount is obtained in a vacuum state. Also, FIG. 15(b) illustrates a model diagram of a SEM in which a sample for measuring the flare amount is obtained in the atmosphere. The display unit 18 and the operation unit 17 prompts a user to input a type, a pressure, an accelerating voltage, and a temperature of gas molecules of a measurement environment and calculates the flare amount from the parameters via a simulation. Alternatively, results of previous simulations regarding typical accelerating voltages and measurement environments may be stored in a database or the like. Also, although FIGS. 15A and 15B illustrate examples of screen images for descriptive purposes, a screen image may not be displayed when the amount of flare is automatically calculated through image processing.

After measuring the flare amount in an actual measurement environment, the sample GAP is obtained from the flare amount obtained by comparing or verifying the measured flare amount with the flare amount calculated through a simulation in the image processing unit. A relationship between the flare amount and the sample GAP may be obtained through a simulation or may be obtained according to a pre-set relationship equation. Alternatively, data regarding the relationship between the flare amount and the sample GAP may be stored in advance, and a sample GAP maybe obtained through a comparison with the data.

As described above, since the sample GAP can be measured according to the present embodiment, a substrate current image having high resolution and high secondary electron selectivity can be obtained.

### Embodiment 5

In the present embodiment, a method of starting automatic setting of observation conditions will be described. A device used in the present embodiment may be applied to the above embodiments.

FIG. 16 illustrates an operation GUI, which is a user interface used in the present embodiment. The operation GUI of FIG. 16 is displayed on the display unit 18. Also, data input is performed through a mouse, a keyboard or the like connected to the operation unit 17. When setting observation conditions the screen image illustrated in FIG. 16 may be automatically started or default values of the observation conditions may be automatically set. For example, the accelerating voltage may be set to the default value. A type of gas in the sample chamber during observation is selected by clicking a gas type button 29, and the pressure of the gas is input. Also, the mean free path is calculated in advance according to the accelerating voltage and stored as a database in a hard disk or a memory. The operation unit 17 gets a mean free path in accordance with the accelerating voltage set as one of measurement conditions. Therefore, the mean free path does not need to be calculated by a user and is automatically set when information regarding gases in a sample chamber is input.

Also, an observation condition setting screen image has an application voltage input window 25, and a user inputs a voltage to be applied to the upper electrode or the lower electrode to the application voltage input window 25. A voltage corresponding to the input value is applied.

Also, the observation condition setting screen image may have a leakage current measurement button 26. The user can measure a substrate current detected at the lower electrode by clicking the leakage current measurement button 26. Therefore, a leakage current may be measured when the leakage current measurement button is pressed under the conditions described in the above embodiment. Also, when an offset button 27 is clicked, the leakage current measured as described in the above embodiment is set as an offset of the substrate current detected at the lower electrode.

The present invention is not limited to the above-described embodiments, but includes various modification examples. For example, the above-described embodiments are described in detail in order to facilitate understanding of the present invention and are not necessarily limited to cases with all the configurations described are prepared. It should be noted that some of the configurations of an embodiment maybe replaced with those of other embodiments, and the configurations of the other embodiments may be added to the configuration of an embodiment. It is also possible to add, delete, or replace the configuration of others according to some of the configuration of each embodiment. In addition, the above-described components, functions, processing units, and processing methods and the like can be partially or entirely implemented in hardware by designing on an integrated circuit, for example. In addition, each of the above-described configurations, functions and the like maybe implemented as software for a processor to interpret and execute the functions thereof.

Information like a program, a table, a file and the like for implementing respective functions can be stored in a recording device, such as a memory, a hard disk, a solid state drive (SSD) and the like, or a recording medium, such as an IC card, an SD card, an optical disk and the like.

Furthermore, control lines and information lines indicate things considered necessary for description, and not all of the control lines and the information lines are necessarily illustrated in a product. In practice, almost all configurations may be considered to be interconnected.

### REFERENCE SIGNS LIST

1: Electron gun, 2: Electro-optical lens barrel, 3: First enclosure, 4: Second enclosure, 5: Sample holder, 6: Deflector, 7: Optical lens, 8: Detector, 9: XYZ stage, 10: Accelerating voltage control unit, 11: Deflection signal control unit, 12: Electron lens control unit, 13: XYZ stage control unit, 14: Detected signal control unit, 15: Image forming unit, 16: Exhaust system control unit, 17: Operation unit, 18: Display unit, 19: Current-to-voltage converting unit, 21: Voltage application control unit, 22: Voltage application unit, 23: Current measuring-processing unit, 24: Image displaying unit, 28: Vacuum pump, 30: Diaphragm unit, 31: Diaphragm, 32: Upper electrode, 33: Lower electrode, 34: Base, 35: Diaphragm holding member, 36: Adhesive, 37: Conductive material, 38: Conductive cap, 39: Sealing member, 40: Insulation material, 41: Insulating film, 42: Resistor, 43: Stage base, 44: Sealing member, 45: Fixing jig, 46: Height adjusting sample stand, 50: Sample cell, 100: Sample, 101: Insulator

1. A charged particle microscope comprising:
a charged particle optical lens barrel that converges a charged particle beam, thereby irradiating a sample with the charged particle beam;
a partition wall that separates a non-vacuum space in which the sample is loaded from a vacuum space inside the charged particle optical lens barrel;
an upper electrode;
a lower electrode on which the sample is loaded;
a power supply for applying a voltage to at least one of the upper electrode and the lower electrode;
a sample gap adjusting mechanism for adjusting a gap between the sample and the partition wall; and
an image forming unit for forming an image of the sample based on a current absorbed by the lower electrode.

2. The charged particle microscope according to claim 1, wherein
the partition wall is a thin film through which the particle beam is transmittable or an orifice through which the charged particle beam passes.

3. The charged particle microscope according to claim 1, wherein
the gap between the sample and the partition wall is adjusted according to a mean free path of the charged particle beam in gases present in the non-vacuum space in which the sample is loaded.

4. The charged particle microscope according to claim 1, wherein
the gap between the sample and the partition wall is adjusted to be three times or less than the mean free path of reflected electrons emitted from the sample in the gases present in the non-vacuum space in which the sample is loaded.

5. The charged particle microscope according to claim 1, wherein
an insulating member or an insulating film is disposed on a surface of the partition wall facing the sample.

6. The charged particle microscope according to claim 1, further comprising:
a leakage current measuring unit for measuring a leakage current absorbed by the lower electrode in a state where the sample is not irradiated with the charged particle beam and an electric field is applied between the upper electrode and the lower electrode, wherein
the image forming unit forms the image based on a current value obtained by subtracting the leakage current from the current absorbed by the lower electrode in a state where the sample is irradiated with the charged particle beam and an electric field is applied between the upper electrode and the lower electrode.

7. The charged particle microscope according to claim 6, further comprising:
a memory for storing a relationship between the magnitude of the leakage current and a gap between the sample and the partition wall; and
a control unit that obtains a gap between the sample and the partition wall based on the magnitude of the leakage current.

8. A method of imaging a sample, the method comprising:
loading a sample on a lower electrode disposed in a non-vacuum space, which is separated from a vacuum space inside a charged particle optical lens barrel by a partition wall;
irradiating the sample with a focused charged particle beam;
applying a voltage to at least one of an upper electrode and the lower electrode;
adjusting a gap between the sample and the partition wall;
measuring a current absorbed by the lower electrode; and
forming an image of the sample based on the current.

9. The method of imaging a sample according to claim 8, wherein
the gap between the sample and the partition wall is adjusted according to a mean free path of emitted electrons emitted from the sample in gases present in the non-vacuum space in which the sample is loaded.

10. The method of imaging a sample according to claim 8, wherein
the gap between the sample and the partition wall is adjusted to be three times or less than the mean free path of reflected electrons emitted from the sample in the non-vacuum space.

11. The method of imaging a sample according to claim 8, further comprising:
measuring a leakage current absorbed by the lower electrode in a state where the sample is not irradiated with the charged particle beam and an electric field is applied between the upper electrode and the lower electrode, wherein
the image is formed based on a current value obtained by subtracting the leakage current from the current absorbed by the lower electrode in a state where the sample is irradiated with the charged particle beam and an electric field is applied between the upper electrode and the lower electrode.
